(19) United States
(12) Patent Application Publication
(10) Pub. No.: US 2006/0220188 A1
(43) Pub. Date: Oct. 5, 2006

(54) Package structure having mixed circuit and composite substrate

(75) Inventors: Chun-Tiao Liu, Hsinchu City (TW); Da-Jung Chen, Taoyuan (TW); Chun-Liang Lin, Tainan (TW); Jeng-Jen Li, Taipei City (TW); Cheng Chieh Hsu, Hsinchu City (TW); Chau Chun Wen, Taoyuan (TW)

Correspondence Address: GENUS LAW GROUP, 5543 TALON COURT, FAIRFAX, VA, 22032, US

(73) Assignee: CYNTEC CO., LTD.

(21) Appl. No.: 11/192,498

(22) Filed: Jul. 29, 2005

(30) Foreign Application Priority Data
Apr. 1, 2005 (TW) 94110616

(51) Int. Cl. H01L 23/495

(52) U.S. Cl. 257/666

(57) ABSTRACT

The present invention provides a package structure, which includes a substrate, wherein the circuit has been configured within the substrate; a lead-frame having lead on the first surface of the substrate; at least one first electronic device located on the lead-frame; a second electronic device located on the first surface of the substrate whose the circuit has been configured therein; a plurality of conductive wires, which used for electrically coupling the first electronic device and second electronic device, and the second electronic device with the lead-frame; a molding compound, which used to seal the portion of substrate, the first electronic device, the second electronic device, and the portion of the lead-frame; and a metal plate, which located on the second surface of the substrate, and used to remove the heat that is generated from the first electronic device.

### BACKGROUND OF THE INVENTION

1. Field of the Invention

The present invention generally relates to a package structure, and more particularly to a package structure having mixed circuit and composite substrate.

2. Description of the Prior Art

At present, the products of the electronic devices tend to light, thin, short, and small. The challenge for the designer is how to integrate the most electronic devices or the circuit lines into a restricted space in a semiconductor device. Therefore, on the basis of this design, the circuit and the electronic device in two dimensions cannot satisfy the design requirement for the high integrated density. Thus, the design of the circuit and electronic device in three dimensions is to be the solution for increasing the integrated density of the electronic device and the circuit.

Referring to FIG. 1 and FIG. 2, which shows the package structure having the DCB (direct copper bond), or IMS (insulated metal substrate) substrate, and electrically couple with the lead-frame by way of the wire bond.

First, referring to FIG. 1 shows the cross-sectional view of the package with the power module. The package structure includes a substrate 100 which is a high dissipated heat substrate, for example, the DCB substrate, or the IMS substrate. The substrate 100 further includes a power device 102, a control device 104, and other electronic devices (not shown) therein/thereon. These electronic devices are electrically coupled with the lead-frame by way of the plurality of conductive wires 112 respectively.

Next, a molding compound 120 is filled into the substrate to cover the control device 104, the power device 102 and other electronic devices on the substrate 100. Further, the plurality of conductive wires 112 electrically coupled the lead-frame 108 with the substrate 100 that is also covered by the molding compound 120, wherein the molding compound 120 is covered the portion of the lead-frame 108. The control device 104, the power device 102 and other electronic devices (not shown) can electrically couple with the external electronic devices by way of the lead 110 of the lead-frame 108.

The disadvantage of the above package structure is that the integrated density of the circuit cannot be increased when the circuit is configured on the substrate 100. Thus, the area of the substrate 100 needs to increase to fit with the circuit configuration, and the fabricating cost would be increased. In addition, the heat is generated from the power device 102, and the heat is transferred to the dissipation sink by way of the heat dissipation paste (not shown), thus, the heat transfer mechanism is not convenient for above package structure design.

Therefore, another package structure is provided to solve the disadvantage of the heat transfer. As shown in FIG. 2, the package structure includes a substrate 100, and a control device 104, a power device 102 and other electronic devices (not shown) are placed on the first surface of the substrate 100 respectively. The plurality of conductive wires 112 is electrically coupled the control device 104, the power device 102 and other electronic devices (not shown) with the lead 110 of the lead-frame 108 and the substrate 100 respectively. Similarly to the above package structure, the molding compound is used to cover the above structure on the substrate 100. The control device 104, the power device 102 and other electronic devices (not shown) is electrically coupled with external electronic device by way of the lead 110 of the lead-frame 108. It is noted that the different between the package structures of FIG. 1 is that a metal plate 130 is formed on the second surface of the substrate 100. Because of the heat efficiency can be improved by the thermal conductivity of the metal plate 130, thus, the heat can be dissipated from the heat dissipation sink (not shown) through the metal plate 130 and to the outside of the package structure. It should be noted that the metal plate 130 is connected with the substrate 100 by way of the solder ball (not shown).

According to abovementioned, the metal plate 130 can increase the heat transfer efficiency for the whole package structure. However, the integrated density of the circuit on the substrate 100 still cannot increased, and the substrate 100 still needs the large area to place the electronic devices.

Referring to FIG. 3 shows the cross-section view of the package structure with the power module. The package structure includes a substrate 100, and a lead-frame 108 is constructed as the circuit lines in/on the first surface of the substrate 100. The control device 104, the power device 102 and other electronic devices are placed on the wafer seat (124). Similarly, the control device 104, the power device 102 and other electronic devices (no shown) is electrically coupled with the lead-frame 108 and the wafer seat 124 respectively. Then, the molding compound 120 is filled into the substrate 100 to cover the above structure. The control device 104, the power device 102 and other electronic devices (not shown) is electrically coupled with the external electronic devices by way of the lead 110 of the lead-frame 108. Furthermore, the package structure further includes a metal plate 130 on the bottom of the substrate 100.

The disadvantage of this package structure is that the lead 110 of the lead-frame 108 should have a specific thickness to strengthen the structure strength. However, the circuit lines of the package structure are constructed by the lead-frame 108, thus, the integrated density and the accuracy of the package structure would be limited. Furthermore, the thermal transfer efficiency is not good due to the thermal transfer is conducted from the package material to the metal plate 130.

### SUMMARY OF THE INVENTION

According to above technology of the conventional prior art, the present invention provides a package structure having a mixed circuit and a composite substrate to improve the thermal efficiency is not good for the package structure, and the problem of the integrated density of the circuit.

It is an object of the present invention is that the power device is formed on the lead-frame, and is electrically coupled with the substrate by the lead-frame. Thus, the substrate can connect the external heat dissipation sink to increase the thermal transfer efficiency, and the substrate also can sustain the heat which is generated from the large current.

It is another object of the present invention, the control device is placed on the substrate which has a configured circuit therein, and the power device is placed on the metal block which is formed on the surface of the substrate. Thus, the heat can be transferred from the metal block and the substrate, and the heat is also transferred to the outside of the package structure by the metal plate which is coupled with the substrate to transfer.

According to above objects, the present invention provides a package structure, which includes a substrate having a configured circuit therein. The lead-frame having the lead is placed on the first surface of the substrate. At least a first electronic device is placed on the lead-frame. A second electronic device is placed on the first surface of the substrate. The plurality of conductive wires electrically coupled the first electronic device with the second electronic device, and the second electronic device is electrically coupled with the lead-frame. A molding compound is sealed the portion of the substrate, the first electronic device, the second electronic device, and the portion of the lead-frame. The metal plate is placed on the second surface of the substrate, and is used to dissipate the heat which is generated from the first electronic device.

The present invention also provides another package structure, which includes a substrate having the configured circuit therein. The lead-frame having a lead is placed on the first surface of the substrate. The plurality of metal blocks is placed on the first surface of the substrate. The each plurality of first electronic devices is placed on the each the plurality of the metal blocks. The second electronic device is placed on the first surface of the substrate. The plurality of conductive wires is electrically coupled the each plurality of first electronic devices therebetween. The plurality of first electronic devices is electrically coupled with the substrate, and the second electronic device is electrically coupled with the substrate by the way of the plurality of conductive wires. The molding compound is sealed the portion of the substrate, the first electronic device, the second electronic device, the plurality of metal blocks, and the portion of the lead-frame. The metal plate is placed on the second surface of the substrate, and is used to dissipate the heat which is generated from the second electronic device.

Thus, due to the circuit is configured on the first surface of the substrate, and the second electronic device can electrically couple with the substrate directly. Therefore, the package structure does not utilize the extra circuit board as the connection between substrate and the heat dissipation sink so that the volume of the package structure can be diminished. Otherwise, the heat transfer efficiency of the package structure can be increased via the substrate that is electrically coupled with the external heat dissipation sink. Thus, the package structure can sustain the heat which is generated from the short time of the large current.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-section view of the package structure having a power module in accordance with the prior art technology;

FIG. 2 is a cross-section view of the package structure having a power module and a metal plate on the bottom surface of the substrate in accordance with the prior art technology;

FIG. 3 is a cross-section view of showing another package structure having a power module in accordance with prior art technology;

FIG. 4A is a cross-section view of showing a package structure having a lead-frame integrated with a substrate that is configured with the circuit therein in accordance with the preferred embodiment of the present invention disclosed herein;

FIG. 4B is a cross-section view of showing a package structure having a substrate without circuit that is configured therein in accordance with the alternative preferred embodiment of the present invention disclosed herein;

FIG. 5A is s cross-section view of showing the package structure having a lead-frame, a metal block, and the substrate having a configured circuit therein in accordance with the preferred embodiment of the present invention disclosed herein; and

FIG. 5B is a cross-section view of showing the package structure having a lead-frame, a metal block, and the substrate without configured circuit therein in accordance with the alternative preferred embodiment of the present invention disclosed herein.

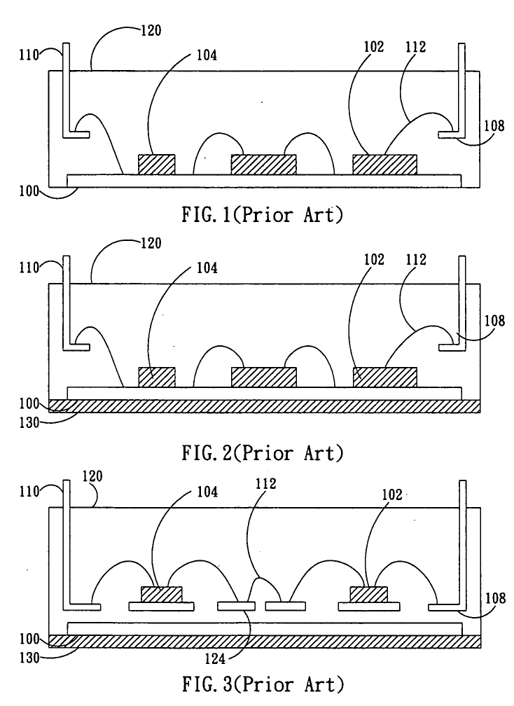

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

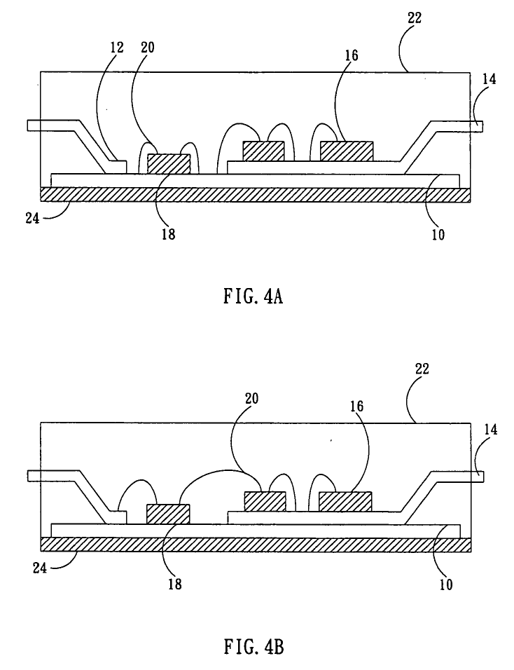

Referring to FIG. 4A, shows the cross-section view of the package structure of the present invention. The package structure includes a substrate 10 having a configured circuit (not shown) in the first surface of the substrate 10. The lead-frame 12 having a lead 14 is placed on the first surface of the substrate 10. The plurality of electronic devices 12 is placed on the lead-frame 12. The second electronic device 18 is placed on the first surface of the substrate 10. The plurality of conductive wires 20 is electrically coupled with each plurality of first electronic devices 16 which is placed on the lead-frame 12. Both the plurality of first electronic devices 16 is electrically coupled with the substrate 10, and the second electronic device 18 is electrically coupled with the substrate 10 by way of the plurality of conductive wires 20. The molding compound 22 is sealed the portion of the substrate 10, the plurality of first electronic devices 16, the second electronic device 18, and the portion of the plurality of conductive wires 12. The metal plate 24 is placed on the second surface of the substrate 10, and is used to dissipate the heat which is generated from the plurality of first electronic devices 16.

According to abovementioned, the substrate having the configured circuit therein that is formed by the thin film, thick film, or mixed of the thin film and the thick film technologies. Because the circuit is configured in the first surface of the substrate 10, the integrated density of the substrate 10 can be increased, and the cost can be decreased. Moreover, the substrate 10 can transfer the heat efficiency due to the substrate 10 has good thermal conductivity. The material of the substrate 10 can be the insulating material, such as ceramic, or the composite material contains the metal, or the composite material of the single surface contains the metal, or the composite material of the double surface contains the metal.

The plurality of first electronic devices 16 is a power device, which means the device would be generated the heat during the operation. The plurality of first electronic devices 16 is placed on the lead-frame 12, and is electrically coupled with the lead-frame 12 by way of the plurality of conductive wires 20. The connection between the plurality of conductive wires 20 and the active surface of the each plurality of first electronic devices 16 is formed by way of wire bond.

Furthermore, the location of the lead-frame 12 can be set on the same flat surface or different flat surface. The material of the lead-frame 12 can be the metal, which is used to transfer the heat, and used as a communication device for the electricity of the package structure. The lead 14 of the lead-frame 12 is used to electrically couple the external electronic devices (not shown).

The following is the key feature of the present invention, the second electronic device 18 is placed on the first surface of the substrate 10 with a configured circuit therein. The placement method includes a several well-known technologies, such as SMT (surface mount technology). Due to the circuit is configured in the first surface of the substrate 10, the conductive wire 20 can be electrically coupled with the first surface of the substrate 10, and the configured circuit on the substrate 10 can couple the electricity between the second electronic device 18 and the lead-frame 12, wherein the conductive wire 20 is placed on the active surface of the second electronic 18.

The metal plate 24 is joined with the solder on the second surface of the substrate 10. By the metal plate 24 has good thermal conductivity, the heat is generated from the plurality of first electronic devices 16 that can be transferred effectively from the lead-frame 12 and through the substrate 10 to the metal plate 24, and the heat can be dissipated to the external heat dissipation sink (not shown). The size of the metal plate 24 would not be limited by the size of the lead-frame 12. Thus, the size or the shape of the metal plate 24 can be designed for the user requirement.

Referring to FIG. 4B, shows the another preferred embodiment of the package structure in this present invention. It is noted that the function of the every electronic devices, and the connection relationship between the every electronic devices are similar to the structure of FIG. 4A. Thus, it would no be described in following embodiment.

The different between FIG. 4B and FIG. 4A is that the substrate 11 is an insulating substrate as in FIG. 4B, and there is no configured circuit in the first surface of the substrate 11. Therefore, the conductive wires 20 is placed on the active surface of the first electronic device 16 that is electrically coupled with the active surface of the second electronic device 18, and the conductive wires 20 is placed on the active surface of the second electronic device 18 that is electrically coupled with the lead-frame 12, wherein the first electronic device 16 is placed on the lead-frame 12. Thus, the first electronic device 16 and the second electronic device 18 is electrically coupled to each other, and the second electronic device 18 and the lead-frame 12 is electrically coupled by way of the conductive wires 20.

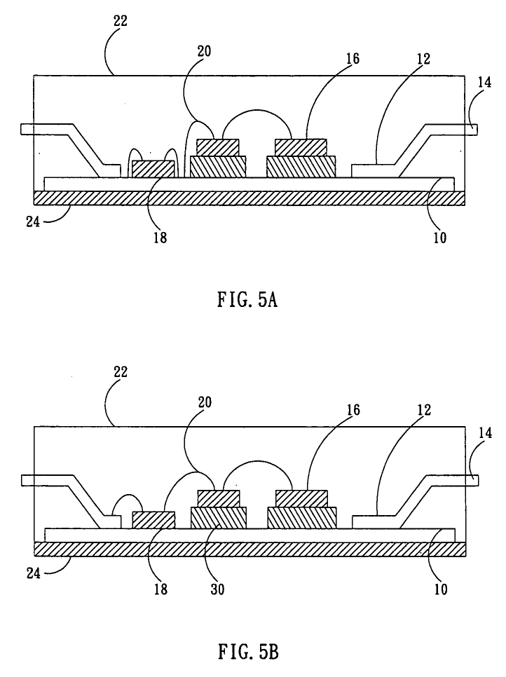

Referring to FIG. 5A, illustrates another alternative preferred embodiment of the package structure in this present invention. The package structure includes a substrate 10 having a configured circuit on the first surface of the substrate 10. The lead-frame 12 having a lead 14 is placed on the first surface of the substrate 10. The plurality of metal blocks 30 is placed on the first surface of the substrate 10. The each plurality of first electronic devices 16 is placed on the each plurality of metal block 30. The second electronic device 18 is placed on the first surface of the substrate 10. The plurality of conductive wires 20 is electrically coupled with the electricity between each plurality of first electronic devices 16, coupled with the electricity between the portion plurality of first electronic devices 16 and the substrate 10, and coupled with the electricity between the substrate 10 and the second electronic device 18. The plurality of conductive wires 20 is placed on the active surface of each plurality of first electronic device 16 and the active surface of the second electronic device 18. The electricity between the portion plurality of first electronic devices 16 and the second electronic device 18 can be electrically coupled by way of the configured circuit in the substrate 10. Similarly, the electricity between the second electronic device 18 and the lead-frame 12 can be electrically coupled by way of the configured circuit in the substrate 10.

Similarly, the molding compound 22 is sealed the portion of the substrate 10, the portion of the lead-frame 12, the plurality of metal blocks 30, the plurality of electronic devices 16, and the second electronic device 18. Then, a metal plate 24 is joined with the solder on the second surface of the substrate 10.

It is noted that the plurality of metal blocks 30 is not only for the electrical communication, but also increased the dissipation heat efficiency. Because the plurality of first electronic devices 16 will generate the heat during the operation, thus, the plurality of first electronic devices 16 is placed on the plurality of metal blocks 30 so as to the heat can be transferred from the plurality of metal blocks 30 through the second surface of the substrate 10 to the external dissipation heat sink (not shown) to increase the dissipation heat efficiency.

Referring to FIG. 5B, shows another preferred embodiment of the present invention. In this preferred embodiment, the substrate 10 having a configured circuit therein as shown in FGI. 5B. However, there is no configured circuit in the substrate 11 in FIG. 5B. Thus, the active surface of the portion first electronic device 16 is placed on the metal block 30 that is electrically coupled with the active surface of the second electronic device 18, and another conductive wires 20 is electrically coupled the active surface of the second electronic device 18 with the lead-frame 12.

According to abovementioned, the lead-frame 12 (as shown in FIG. 4A or FIG. 4B) or the metal block 30 (as shown in FIG. 5A or FIG. 5B) are used as the dissipation devices in the package structure. The objective of the lead-frame 12 or the metal block 30 is used for increasing the dissipation heat efficiency. The advantage of the second electronic device 18 is placed directly on the substrate 10 such that the space, volume and the area of the package structure can be diminished.

Although specific embodiments have been illustrated and described, it will be obvious to those skilled in the art that various modifications may be made without departing from what is intended to be limited solely by the appended claims.

What is claimed is:

1. A package structure, comprising:
a substrate having a first surface and a second surface;
a lead-frame having a pin on said first surface of said substrate;
a plurality of first electronic devices on said lead-frame;
a second electronic device on said first surface of said substrate;
a plurality of conductive wires electrically coupling with each said plurality of first electronic devices, a portion of said plurality of first electronic devices, and said second electronic device, and electrically coupling with said second electronic device and said lead-frame; and
a metal plate placing on said second surface of said substrate.

2. The package structure according to claim 1, wherein said substrate having a configured circuit therein.

3. The package structure according to claim 1, wherein the material of said substrate is an insulating material.

4. The package structure according to claim 3, wherein the material of said insulating material is a ceramic.

5. The package structure according to claim 3, wherein said insulating material having a single surface that comprises a composite material of a metal.

6. The package structure according to claim 3, wherein said insulating material having a double surface that comprises a composite material of a metal.

7. The package structure according to claim 1, wherein said plurality of said first electronic devices is power device.

8. The package structure according to claim 1, wherein said second electronic device is a control device.

9. The package structure according to claim 1, wherein said plurality of conductive wires placed on an active surface of each said plurality of first electronic devices, an active surface of said second electronic device, and said lead-frame respectively.

10. The package structure according to claim 1, wherein said plurality of conductive wires placed on an active surface of each of said plurality of first electronic devices, an active surface of said second electronic device, and said first surface of said substrate respectively.

11. A package structure, comprising:
a substrate having a first surface and a second surface, and a metal plate placing on said second surface;
a lead-frame having a lead that placing on said first surface of said substrate;
a plurality of metal blocks placing on said first surface of said substrate;
a plurality of first electronic devices, each said plurality of first electronic devices placing on each said plurality of metal blocks;
a second electronic device placing on said first surface of said substrate; and
a plurality of conductive wires electrically coupling each said plurality of first electronic devices, portion of each said plurality of first electronic devices, and said second electronic device, and said electrically coupling said second electronic device and said lead-frame.

12. The package structure according to claim 11, wherein said substrate having a configured circuit therein.

13. The package structure according to claim 11, wherein the material of said substrate is an insulating material.

14. The package structure according to claim 13, wherein the material of said insulating material is ceramic.

15. The package structure according to claim 13, wherein said insulating material having a single surface that comprises a composite material of a metal.

16. The package structure according to claim 13, wherein said insulating material having a double surface that comprises a composite material of a metal.

17. The package structure according to claim 11, wherein said plurality of first electronic devices is power device.

18. The package structure according to claim 11, wherein said second electronic device is control device.

19. The package structure according to claim 11, wherein said plurality of conductive wires placed on an active surface of each of said plurality of first electronic devices, an active surface of said second electronic device, and said lead-frame respectively.

20. The package structure according to claim 11, wherein said plurality of conductive wires placed on an active surface of each of said plurality of first electronic devices, an active surface of said second electronic device, and said first surface of said substrate respectively.
